(19) United States
(12) Patent Application Publication
(10) Pub. No.: US 2022/0246547 A1
(43) Pub. Date: Aug. 4, 2022

(54) ELECTRONIC DEVICE INCLUDING ONE OR MORE MONOLAYER AMORPHOUS FILMS AND METHOD OF FORMING THE SAME

(71) Applicant: National University of Singapore, Singapore (SG)

(72) Inventors: Barbaros OEZYILMAZ, Singapore (SG); Chee Tat TOH, Singapore (SG); Irfan Haider ABIDI, Singapore (SG)

(21) Appl. No.: 17/640,669

(22) PCT Filed: Sep. 18, 2020
(86) PCT No.: PCT/SG2020/050536

§ 371 Date: Mar. 4, 2022

(30) Foreign Application Priority Data
Sep. 20, 2019 (SG) 10201908768S

(51) Int. Cl. H01L 23/00; H01L 51/00; H01L 51/56; H01L 23/14; H01L 23/532; H01L 21/02

(52) U.S. Cl. CPC H01L 23/564; H01L 51/0097; H01L 51/56; H01L 23/145; H01L 23/142; H01L 51/5237; H01L 23/53238; H01L 21/02271; H01L 21/02592; H01L 21/02554; H01L 23/5329

(57) ABSTRACT

Various embodiments relate to an electronic device including a substrate comprising a semiconductor or polymeric inhibit and a barrier comprising one or more monolayer amorphous films over the substrate, wherein the barrier is configured to or reduce permeation of moisture or gas from environment to the substrate. Various embodiments relate to an electronic device comprising a first device structure including an electrically conductive material, a second device structure including a further electrically conductive material or a semiconductor material, and a barrier including one or more monolayer amorphous films between the first device structure and the second device structure, wherein the barrier is configured to inhibit or reduce interdiffusion between the first device structure and the second device structure. In specific embodiments, the electronic device is an organic light emitting diode (OLED) or a thin film transistor (TFT), and the monolayer amorphous films are monolayer amorphous carbon (MAC) films.

### CROSS-REFERENCE TO RELATED APPLICATION

This application claims the benefit of priority of Singapore application No. 10201908768S filed Sep. 20, 2019, the contents of it being hereby incorporated by reference in its entirety for all purposes.

### TECHNICAL FIELD

Various aspects of this disclosure relate to an electronic device including one or more monolayer amorphous films (MAFs). Various aspects of this disclosure relate to a method of forming an electronic device including one or more monolayer amorphous films (MAFs).

### BACKGROUND

Flexible electronic devices such as organic light-emitting diode (OLED) displays, thin film transistors (TFTs), perovskite and organic solar cells have polymeric substrates so that the devices are transparent, flexible, and have low power consumption. However, for example, the organic materials employed as the self-emitting component in OLED displays are highly vulnerable to the moisture and atmospheric oxygen, especially in humid conditions. Humidity gradually degrades the functionality of the devices. Therefore, a protective barrier layer or film is required to protect OLED displays, or other organic or perovskite solar cell devices from oxygen and moisture penetration, so that the lifespan of such devices can be prolonged. The quality of the barrier layer of film is evaluated by the oxygen penetration content, as well as the water vapor transmission rate (WVTR).

Polymeric coatings, such as parylene C, polyethylene terephthalate (PET), metallized polyethylene terephthalate/polyethylene (PET/PE) have been traditionally used as barrier layers, as they maintain the flexibility and transparency of the OLED displays. However, the polymeric coatings provide limited protection, as they are vulnerable to moisture and oxygen and are mechanically weak under stress. Alternatively, inorganic materials, such as glass, silicon dioxide (SiO₂), silicon nitride (SiN), aluminum oxide (Al₂O₃), are mechanically strong and provide adequate protection at certain thickness against moisture. However, barriers or films including these inorganic materials are rigid and compromises the flexibility and transparency of the devices. Moreover, the fabrication of these inorganic materials barriers or films typically employs atomic layer deposition (ALD), which induces unwanted pinholes defects in the barriers or films and takes much longer processing time, thereby rendering such an encapsulation technology less efficient.

On a separate note, copper (Cu) and cobalt (Co) interconnects are typically used in silicon (Si)-based integrated circuits due to their superior conductivity and low line resistance, allowing miniaturization of microelectronic devices. However, Cu and Co face the problem of interdiffusion with underlying silicon (Si) or dielectric chips, consequently corrupting device operability. Therefore, a diffusion barrier layer on interconnects is required to prevent Cu or Co migration. However, the ideal diffusion barrier should bear properties such as strong adherence to Cu or Co, ultrathin, and thermally stable.

The International Roadmap for Devices and Systems (IRDS) 2017 reveals that one of the major challenges of technology miniaturization and ultra large scale integration (ULSI) is further scaling of the interconnects, which is currently limited by the requisite minimum thickness of diffusion barrier material. FIG. 1 shows the International Technology Roadmap for Semiconductors. Conventional diffusion barriers are typically 10 nm of ALD-grown titanium nitride (TiN) or tantalum nitride (TaN). The thickness is required to prevent Cu and Co ions from diffusing into the semiconductor layer. However, such a thickness is too large to meet future device scaling, as shown in FIG. 1. Moreover, the thicker layer of highly resistive barrier material significantly increases the resistivity of the Cu interconnects and thus badly affects device performance. Therefore, the International Roadmap for Semiconductors (http://www.itrs2.net/) anticipates an atomically thin diffusion barrier material with thickness less than 2 nm to realize ultra-scaled future devices. Moreover, candidates for the diffusion barrier need to be inert to both interfaces and have a strong adhesion. Challenges the industry are currently facing relate to reducing the thickness of the barriers, as well as reducing the process temperature to fabricate the diffusion barriers at temperatures less than 400° C. to avoid diffusion of dopants.

### SUMMARY

Various embodiments may relate to an electronic device. The electronic device may include a substrate including suitable semiconductor or a suitable polymeric material. The electronic device may also include a barrier including one or more monolayer amorphous films over the substrate. The barrier may be configured to inhibit or reduce permeation of moisture or gas from environment to the substrate.

Various embodiments may relate to a method of forming an electronic device. The method may include forming a barrier comprising one or more monolayer amorphous films on a substrate. The substrate may include a suitable semiconductor or a suitable polymeric material. The barrier may be configured to inhibit or reduce permeation of moisture or gas from environment to the substrate.

Various embodiments may relate to an electronic device. The electronic device may include a first device structure including an electrically conductive material. The electronic device may also include a second device structure including a further electrically conductive material or a semiconductor material. The electronic device may further include a barrier including one or more monolayer amorphous films between the first device structure and the second device structure. The barrier may be configured to inhibit or reduce interdiffusion between the first device structure and the second device structure.

Various embodiments may relate to a method of forming an electronic device. The method may include forming a first device structure including an electrically conductive material. The method may also include forming a second device structure including a further electrically conductive material or a semiconductor material. The method may further include forming a barrier comprising one or more monolayer amorphous films between the first device structure and the second device structure. The barrier may be configured to inhibit or reduce interdiffusion between the first device structure and the second device structure.

### BRIEF DESCRIPTION OF THE DRAWINGS

The invention will be better understood with reference to the detailed description when considered in conjunction with the non-limiting examples and the accompanying drawings, in which:

FIG. 1 shows the International Technology Roadmap for Semiconductors.

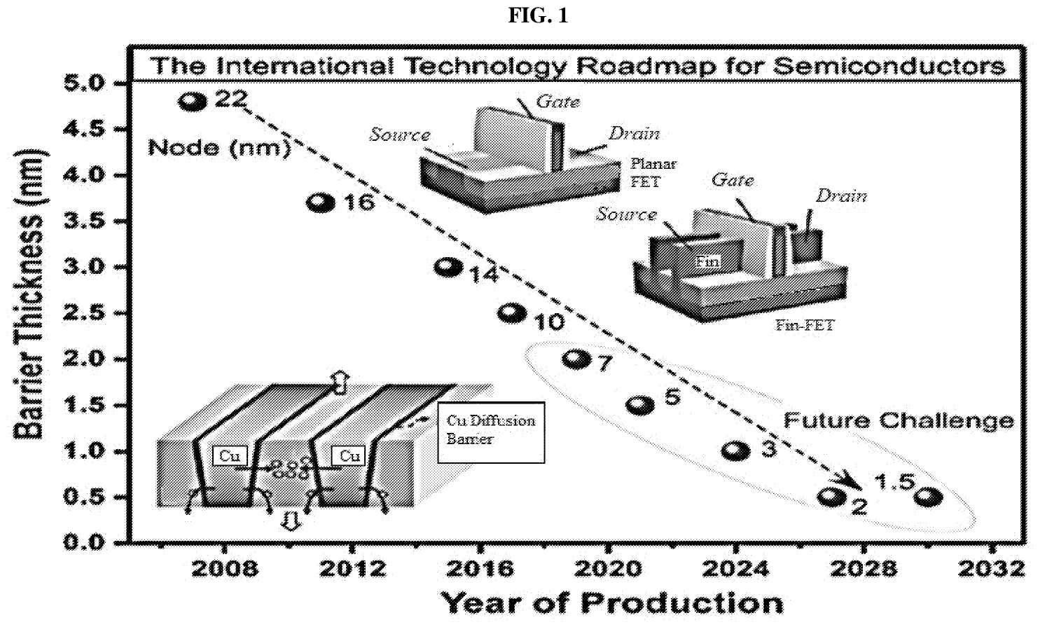

FIG. 2 is a schematic illustrating an electronic device according to various embodiments.

FIG. 3 is a schematic illustrating a method of forming an electronic device according to various embodiments.

FIG. 4 is a schematic illustrating an electronic device according to various embodiments.

FIG. 5 is a schematic illustrating a method of forming an electronic device according to various embodiments.

FIG. 6 shows a schematic of a device including monolayer amorphous carbon (MAC) film over a substrate according to various embodiments.

FIG. 7 is a schematic showing a device including a substrate and a monolayer amorphous carbon (MAC) film over the substrate according to various embodiments, with inset showing amorphous atomic arrangements.

FIG. 8 shows (left) an optical image of graphene encapsulated copper after 4 months of aging in ambient atmosphere; and (right) an optical image of monolayer amorphous carbon (MAC) encapsulated copper according to various embodiments after 4 months of aging in ambient atmosphere.

FIG. 9 shows (left) an optical image showing crack propagation along grain boundaries of graphene after indentation; and (right) an optical image of a monolayer amorphous carbon (MAC) film according to various embodiments showing lack of crack propagation after indentation.

FIG. 10A shows (above) an atomic force microscopy (AFM) image of a suspended monolayer amorphous carbon (MAC) film according to various embodiments after an indentation is made on the film; and (below) a graph of height (in nanometers or nm) as a function of distance (in nanometers or nm) showing the corresponding height profile which shows an indentation peak after the AFM is pulled out of the monolayer amorphous carbon (MAC) film.

FIG. 10B shows (above) another atomic force microscopy (AFM) image of the suspended monolayer amorphous carbon (MAC) film according to various embodiments after a second indentation is made on the film (on the right of the first indentation); and (below) a graph of height (in nanometers or nm) as a function of distance (in nanometers or nm) showing the corresponding height profile which shows a second indentation peak after the AFM is pulled out of the monolayer amorphous carbon (MAC) film.

FIG. 10C shows a three-dimensional atomic force microscopy (AFM) image of the suspended monolayer amorphous carbon (MAC) film according to various embodiments with two indentations.

FIG. 11 shows (left) an optical image of a bubble test in which some holes are covered by monolayer amorphous carbon (MAC) films according to various embodiments and gas is introduced such that the monolayer amorphous carbon (MAC) films each forms a bulge; and (right) an atomic force microscopy (AFM) image showing the bulging of the monolayer film after removal from a higher pressure gas chamber.

FIG. 12 shows a plot of transmittance (in percent or %) as a function of wavelength (in nanometer or nm) illustrating the transmittance spectrum of monolayer amorphous carbon (MAC) according to various embodiments.

FIG. 13A shows a scanning electron microscopy image of copper (Cu) lines after monolayer amorphous carbon (MAC) films are grown over the copper lines using laser chemical vapor deposition according to various embodiments.

FIG. 13B shows an atomic force microscopy (AFM) image of copper (Cu) lines after monolayer amorphous carbon (MAC) films are grown over the copper lines using laser chemical vapor deposition according to various embodiments.

FIG. 13C is a plot of Raman intensity (arbitrary units or a.u.) as a function of wavenumber (in per centimeter of 1/cm) showing the Raman spectrum of monolayer amorphous carbon (MAC)/copper (Cu) lines with D and G bands according to various embodiments.

FIG. 14A shows atomic force microscopy (AFM) images of (left) uncoated copper (Cu) lines before exposure to ammonium persulfate (APS); and (middle and right) the uncoated copper (Cu) lines after exposure to ammonium persulfate (APS).

FIG. 14B shows atomic force microscopy (AFM) images of (left) monolayer amorphous carbon (MAC)-coated copper (Cu) lines according to various embodiments before exposure to ammonium persulfate (APS); and (middle and right) the monolayer amorphous carbon (MAC)-coated copper (Cu) lines according to various embodiments after exposure to ammonium persulfate (APS).

FIG. 15 shows (left) a scanning electron microscopy (SEM) image of monolayer amorphous carbon (MAC) coated copper (Cu) foils according to various embodiments after being exposed to acid; (middle) graphene coated copper (Cu) foils after being exposed to acid; and (right) a plot comparing the copper (Cu) ions lost (in parts per million or ppm) of a standard copper (Cu) electrode, a graphene coated (Cu) electrode, and a monolayer amorphous carbon (MAC) coated copper (Cu) electrode according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The device as described herein may be operable in various orientations, and thus it should be understood that the terms “top”, “bottom”, etc., when used in the following description are used for convenience and to aid understanding of relative positions or directions, and not intended to limit the orientation of the device.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may relate to an electronic device including one or more monolayer amorphous films (MAFs), which may alternatively be referred to as two-dimensional (2D) amorphous films.

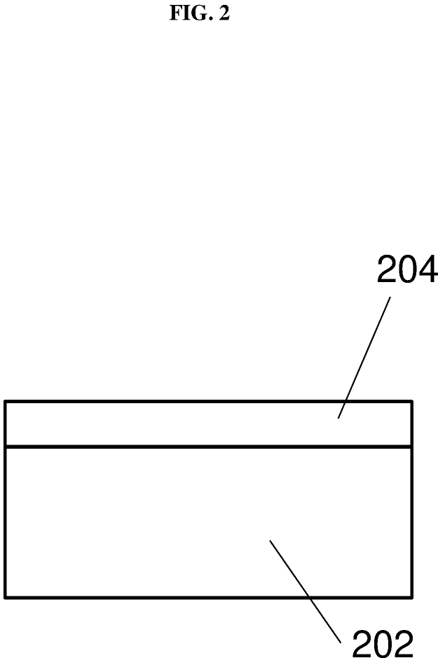

FIG. 2 is a schematic illustrating an electronic device according to various embodiments. The electronic device may include a substrate 202 including a suitable semiconductor or a suitable polymeric material. The electronic device may also include a barrier 204 including one or more monolayer amorphous films (MAF) over the substrate 202. The barrier 204 may be configured to inhibit or reduce permeation of moisture or gas, e.g. oxygen, from environment to the substrate.

For avoidance of doubt, FIG. 2 does not limit the shape, size, orientation etc. of the device or its various components. For instance, while FIG. 2 shows a substrate 202 with rectangular cross-sectional area, various embodiments may include a substrate of any suitable shape. Further, although FIG. 2 shows a barrier 204 with a single monolayer amorphous film, various embodiments may include a barrier 204 with more than one monolayer amorphous films.

In the current context, an “amorphous solid” may refer to a solid that lacks the long-range order that is characteristic of a crystal.

In the current context, the term “monolayer” may refer to an one-atom thick layer.

The one or more monolayer amorphous films may include, but are not limited to monolayer amorphous carbon (MAC) films, amorphous boron nitride (a-BN) films, monolayer amorphous molybdenum disulfide films, monolayer amorphous tungsten disulfide films, monolayer amorphous borophene (a-BP) films, other monolayer amorphous transition metal dichalcogenide (a-TMDs) films, monolayer amorphous boron carbon nitride films, or heterogenous atomic doped films and alloys.

In the current context, the term “amorphous carbon” may refer to carbon structure that does not have a long-range order or crystalline structure. A monolayer amorphous carbon (MAC) film may alternatively be referred to as an atomic layer of sp² bonded carbon making a two-dimensional amorphous carbon (2DAC) film. In this regard, the monolayer amorphous carbon (MAC) film may have a structure and properties different from bulk amorphous carbon, i.e. diamond-like carbon, glassy carbon, soot etc. For instance, bulk amorphous carbon may be permeable to moisture and gases such as oxygen, and may not be suitable as an interdiffusion barrier. On the other hand, graphene is an atomic layer of sp²- bonded carbon lattice, forming a crystalline material (either single crystal or polycrystalline). For graphene to be synthesized, it requires high temperatures and is mostly limited to transition metal substrates (Cu, Ni, Co etc) for growth. In contrast, MAC may be formed at much lower temperatures and on arbitrary substrates. Similarly, other monolayer amorphous films (MAFs) may have a structure and properties different from their bulk and 2D crystalline counterparts.

In various embodiments, each of the one or more monolayer amorphous films may have a thickness selected from a range from 0.4 nm to 1 nm.

In various embodiments, the one or more monolayer amorphous films may form a stack.

In various embodiments, the electronic device may further include a protective layer over the substrate 202. The protective layer may include an oxide or a polymer. The oxide may be aluminum oxide (Al₂O₃) or hafnium oxide (HfO₂). The polymer may be parylene C. The protective layer may be formed or deposited via atomic layer deposition (ALD) techniques. The protective layer may be included as part of the barrier 204.

In various embodiments, the one or more monolayer amorphous films may be between the protective layer and the substrate 202. In various other embodiments, the protective layer may be between the one or more amorphous films and the substrate 202.

In various embodiments, the electronic device, may be, but is not limited, to an organic light emitting diode (OLED) or a thin film transistor (TFT). For instance, the OLED may include a first electrode, a second electrode and an organic emission layer between the first electrode and the second electrode. The emission layer may be on the first electrode and the second electrode may be on the emission layer. The second electrode may for instance include an electrically conductive material, e.g. a semiconductor such as indium tin oxide. The emission layer may include a polymer that is configured to emit light upon application of a potential difference across the emission layer. The barrier 204 including the one or more amorphous films may be provided on the second electrode and/or on the organic emission layer. On the other hand, a top-gate TFT may include a layer of semiconductor material, e.g. amorphous silicon, a dielectric layer on the layer of semiconductor material, a gate electrode on the dielectric layer, and a drain electrode and a source electrode at least partially embedded in the layer of semiconductor layer. The drain electrode and the source electrode may be on a first side of the dielectric layer, and the gate electrode may be on a second side of the dielectric layer opposite the first side. The gate electrode may include a semiconductor such as ITO. The barrier 204 including the one or more amorphous films may be provided on the gate electrode. A bottom-gate TFT may include a gate electrode, a dielectric layer on the gate electrode, and a drain electrode and a source electrode on or over the dielectric layer. The bottom-gate TFT may include a layer of semiconductor material, e.g. silicon, over the source and drain electrodes. The barrier 204 including the one or more amorphous films may be provided on the layer of semiconductor material.

In various embodiments, the one or more monolayer amorphous films may include predominantly sp² bonds. In various embodiments, a bond ratio of sp^{a} /sp² present in the one or more monolayer amorphous films may be 0.1 or less.

In various embodiments, the one or more monolayer amorphous films may have an oxygen penetration content selected from a range from 10⁻⁴ cc m⁻² day⁻¹ to 10⁻² cc m⁻² day⁻¹, or even of less than 10⁻⁴ cc m⁻² day⁻¹. In various embodiments, the one or more monolayer amorphous films may have a water vapor transmission rate (WVTR) selected from a range from 10−5 g m ⁻² day⁻¹, or even of less than 10⁻⁵g m⁻² day⁻¹.

In various embodiments, the one or more monolayer amorphous films may have a transparency greater than 95%, e.g. greater than 98%, e.g. 98.1% (measured at 550 nm). In various embodiments, the one or more monolayer amorphous films may have a sheet resistance of 100 GΩ/□ or greater. A monolayer amorphous film may have a mixture of hexagonal and non-hexagonal rings. Non-hexagonal rings may be in a form of 4-, 5-, 7-, 8-, 9-membered rings. The rings may be fully connected to one another, forming a network of polygons in a large area film whose scale is at least in microns. Crystallinity may refer to a degree of structural order in a solid, and may be measured based on a ratio of hexagonal rings to non-hexagonal rings. In the current context, a monolayer amorphous film may be a film having a crystallinity (C) equal or less than 80% (C≤80%). In various embodiments, such as an amorphous MAC film, the crystallinity may be equal or greater than 60% (C≥60%). The crystallinity of the one or more monolayer amorphous films may be tuned to any suitable value between 60% and 80% (inclusive of both end values), such that the barrier properties may correspondingly be changed.

In various embodiments, the suitable semiconductor may, for instance, be silicon, germanium, gallium arsenide (GaAs), indium gallium zinc oxide (IGZO), zinc oxide (ZnO) etc. In various embodiments, the suitable polymeric material may, for instance, be silicon oxide (SiO₂), polyethylene terephthalate (PET), polyphenylene vinylene (PPV), polyfluorene (PF), poly(p-phenylene) (PPP) etc.

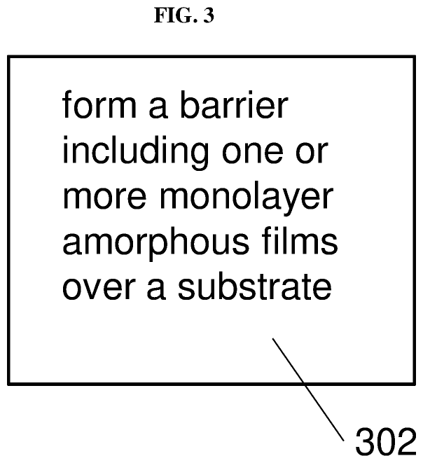

FIG. 3 is a schematic illustrating a method of forming an electronic device according to various embodiments. The method may include, in 302, forming a barrier comprising one or more monolayer amorphous films over a substrate. The substrate may include a suitable semiconductor or a suitable polymeric material. The barrier may be configured to inhibit or reduce permeation of moisture or gas, e.g. oxygen, from environment to the substrate.

In various embodiments, the one or more monolayer amorphous films may be formed on the substrate via a chemical vapor deposition (CVD) process. In various embodiments, the chemical vapor deposition process is a laser chemical vapor deposition (LCVD) process. A temperature in which the chemical vapor deposition process is carried out may be any suitable temperature below 300° C.

In various embodiments, the one or more monolayer amorphous films or barrier may be formed as free-standing films before being transferred onto the substrate. In other words, the one or more monolayer amorphous films or barrier may be formed and may subsequently be transferred onto the polymeric or semiconductor substrate without using polymethylmethacrylate (PMMA) support.

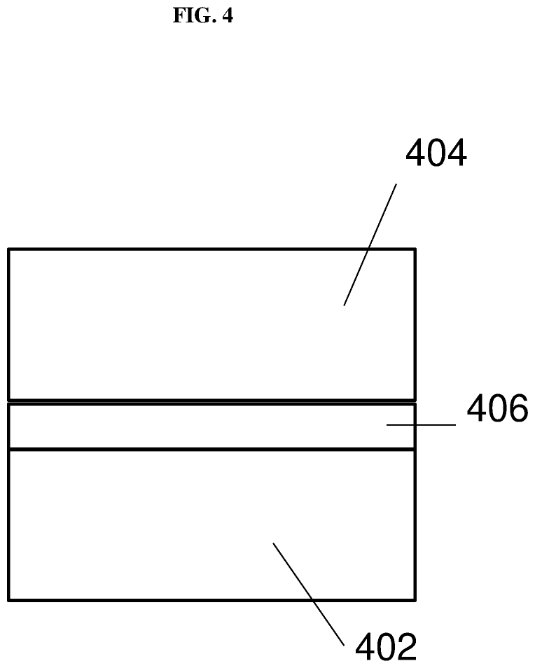

FIG. 4 is a schematic illustrating an electronic device according to various embodiments. The electronic device may include a first device structure 402 including an electrically conductive material. The electronic device may also include a second device structure 404 including a further electrically conductive material or a semiconductor material. The electronic device may further include a barrier 406 including one or more monolayer amorphous films between the first device structure 402 and the second device structure 404. The barrier 406 may be configured to inhibit or reduce interdiffusion between the first device structure and the second device structure.

For avoidance of doubt, FIG. 4 does not limit the shape, size, orientation etc. of the device or its various components. For instance, while FIG. 4 shows structures 402, 404 with identical, rectangular cross-sectional areas, various embodiments may include structures of any suitable shape. In various embodiments, the shape of structure 402 may be different from the shape of structure 404. Further, although FIG. 4 shows a barrier 406 with a single monolayer amorphous film, various embodiments may include a barrier 406 with more than one monolayer amorphous films.

In various embodiments, the electrically conductive material may be a metal, a metal alloy, a doped metal oxide, or conductive carbon. In various embodiments, the electrically conductive material or metal may be copper (Cu) or cobalt (Co).

In various embodiments, the further electrically conductive material may be a metal, a metal alloy, a doped metal oxide, or conductive carbon.

In various embodiments, the semiconductor material may, for instance, be silicon, germanium, gallium arsenide (GaAs), indium gallium zinc oxide (IGZO), zinc oxide (ZnO), or any other suitable semiconductor material.

In one example, the one or more monolayer amorphous films may be between two interconnects. In other words, the first device structure 402 may be a first interconnect, and the second device structure 404 may be a second interconnect.

In another example, the one or more monolayer amorphous films may be between an interconnect and a substrate. In other words, the first device structure 402 may be an interconnect, and the second device structure may be a substrate, e.g. a semiconductor substrate such as a silicon substrate, a germanium substrate, a gallium arsenide (GaAs) substrate, an indium gallium zinc oxide (IGZO) substrate, a zinc oxide (ZnO) substrate etc. In yet another example, the one or more amorphous films may be between two metal contacts such as gate metal stacks.

In various embodiments, a bond ratio of sp³/sp² present in the one or more monolayer amorphous films may be 0.1 or less.

In various embodiments, the electronic device may be, but is not limited to, a transistor, a diode, a memory device, or an electro-mechanical device, an integrated circuit chip, a microprocessor, or an electronic sensing device.

Various embodiments may relate to a circuit arrangement including the electronic device as described herein.

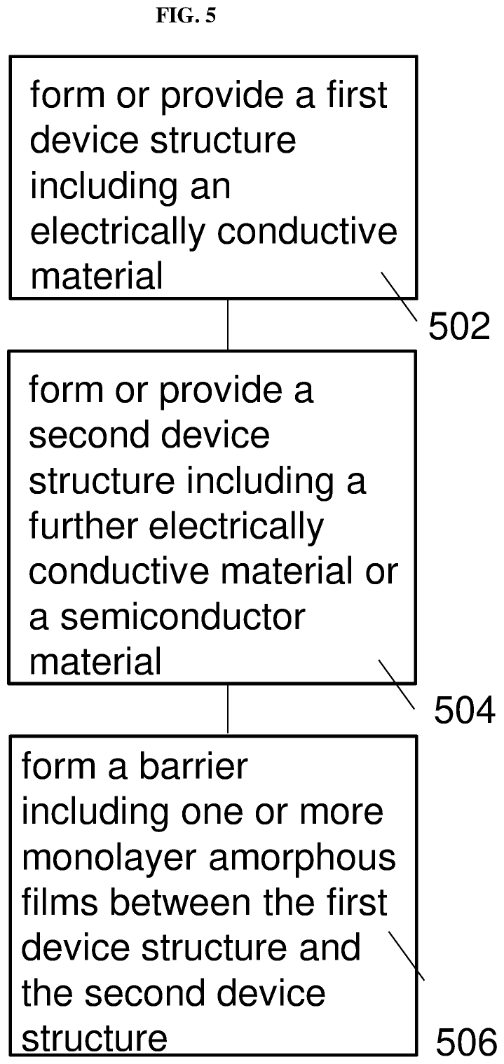

FIG. 5 is a schematic illustrating a method of forming an electronic device according to various embodiments. The method may include, in 502, forming or providing a first device structure including an electrically conductive material. The method may also include, in 504, forming or providing a second device structure including a further electrically conductive material or a semiconductor material. The method may further include, in 506, forming a barrier including one or more monolayer amorphous films between the first device structure and the second device structure. The barrier may be configured to inhibit or reduce interdiffusion between the first device structure and the second device structure.

For avoidance of doubt, FIG. 5 does not indicate or limit the sequence of the various steps. In various embodiments, step 506 may occur before step 504, and step 502 may occur after step 504.

In various embodiments, the first device structure may be formed over the one or more monolayer amorphous films after forming the one or more monolayer amorphous films over the second device structure such that the one or more monolayer amorphous films are between the first device structure and the second device structure.

In various embodiments, the one or more monolayer amorphous films may be formed via a chemical vapor deposition process (CVD). The chemical vapor deposition process may be a laser chemical vapor deposition process (LCVD).

In various embodiments, a temperature in which the chemical vapor deposition process is carried out may be any suitable temperature below 300° C.

In various embodiments, the one or more monolayer amorphous films may be formed as free-standing films before being transferred over the second device structure.

Monolayer amorphous films (MAFs), such as monolayer amorphous carbon (MAC) films, may potentially be grown directly on polymeric or semiconductor substrates using processes such as low-temperature and ultrafast laser-based CVD (chemical vapor deposition), making this an industrially viable encapsulation method. Mono- to multilayer MAC have been shown to block atoms bigger than protons due to the homogeneous atomic structure. Therefore, MAC film is expected to keep the water vapor transmission rate (WVTR) at less than 10⁻⁵ g m⁻² day⁻¹, at least 2 orders of magnitude better than graphene, which has a WVTR of 10⁻³-10⁻¹ g m⁻² day⁻¹.

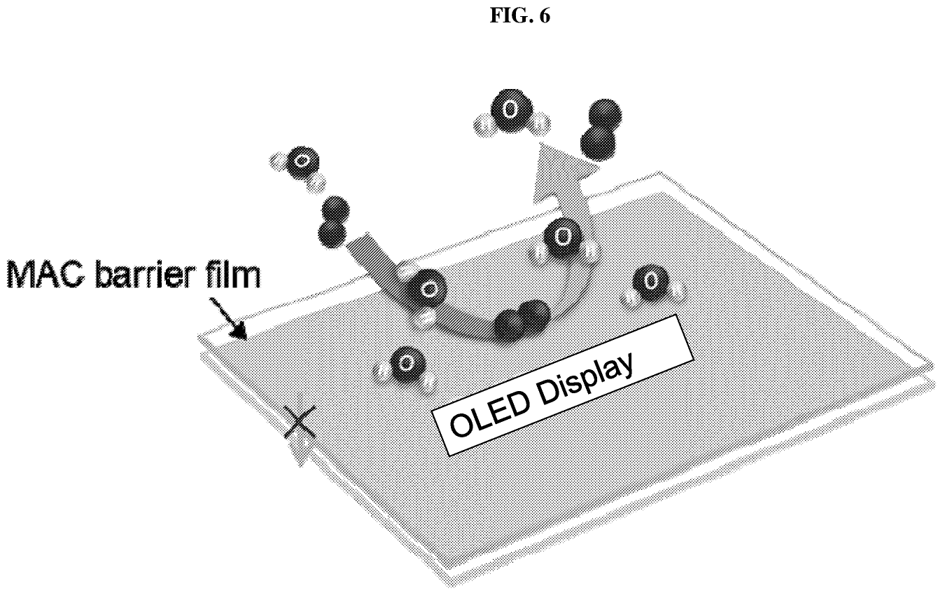

FIG. 6 shows a schematic of a device including monolayer amorphous carbon (MAC) film over a substrate according to various embodiments. MAC has a transparency >98.1%, which may be higher than any other conventional ultrathin barrier films. As such, MAC may be ideal for transparent OLEDs.

One cause of failure of existing flexible devices may be attributed to mechanical fracture of the inorganic barrier films under bending through crack propagation without plastic deformation, resulting in the shorter lifetime. However, MAC films possess higher fracture toughness, which induces higher plasticity with reduced or minimal crack propagation in the barrier film, thereby enhancing the durability of MAC barrier layer and flexibility of devices.

In addition, MAFs may be used in diffusion barrier owning to their superior properties such as thermal stability, chemical inertness and being atomically thin. Monolayer amorphous films (MAFs) such as MAC may be formed between the semiconductor substrate and interconnects. MAC may be directly grown on semiconductor layers of silicon (Si) or germanium (Ge) before forming of copper (Cu) interconnects. A corrosion test shows that MAC may reduce copper (Cu) oxidation and corrosion rate of copper by greater than 7 times compared to graphene coated copper (Cu) and uncoated copper (Cu). MAFs may be used in diffusion barriers (e.g., in backend of line (BEOL), or even front end of line (FEOL)) as they have been established to reduce or block diffusion of both copper (Cu) and cobalt (Co), which is targeted to replace copper (Cu).

The chemical inertness of MAC may be advantageous as compared to the other metallic diffusion barrier layers employed, such as titanium (Ti), palladium (Pd) etc., which react with copper (Cu) at higher temperatures. As MAC is insulating, MAC may avoid possible short-circuiting of the (Cu) interconnects. Concurrently, the higher thermal conductivity of MAC may provide faster thermal spread resulting in efficient thermal management of high-power density devices.

While experimental data provided herein relate primarily to monolayer amorphous carbon (MAC) films, other monolayer amorphous films (MAFs) may be expected to have similar characteristics, and may be used in similar applications. These other MAFs, may include, for instance, amorphous boron nitride films, monolayer amorphous molybdenum disulfide films, monolayer amorphous tungsten disulfide films, monolayer amorphous borophene films, monolayer amorphous transition metal dichalcogenide films, monolayer amorphous boron carbon nitride films, or heterogenous atomic doped films or alloys.

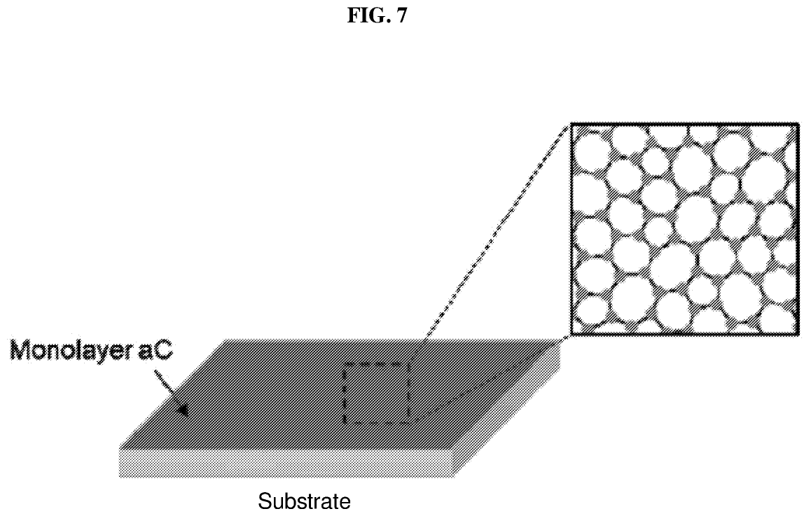

FIG. 7 is a schematic showing a device including a substrate and a monolayer amorphous carbon (MAC) film over the substrate according to various embodiments, with inset showing amorphous atomic arrangements.

Various embodiments may relate to a device in which the amorphous carbon film overs the entire substrate. Various embodiments may find applications for instance as a carbon coating. The monolayer amorphous carbon film may also serve as a diffusion barrier, i.e. permeation barrier, without defects, thereby preventing the underlying substrate from oxidation and corrosion. Due to its electrically insulating properties, the amorphous carbon film may reduce or prevent galvanic corrosion of substrate.

Table 1 below list some of the features and associated benefits/advantages of various embodiments of the present invention.

TABLE 1

| Feature | Benefit/Advantage |
|---|---|
| Nanometer thickness of 2D amorphous film | Atomically thin, MAC has been shown to |
| (including but not limited to MAC), as | block all atoms bigger than protons. |
| protective film or diffusion barrier layer. | Thickness is important for the bending radius |
| Impermeable barrier to all atoms even at <2 | of flexible devices. Currently, it is quite |
| nm. | challenging to bend to <1 mm radius in |
| | existing organic barriers. Single layer MAC |
| | may have a thickness in the range of 0.4 nm |
| | to 1 nm. |
| | MAC may be chemically stable with a |
| | homogenous atomic structure that does not |
| | have preferential weaker sites which are |
| | prone to the attack by the reactive atmosphere |
| | (oxygen, moisture). e.g. at grain boundaries |
| | in crystalline materials. |
| | MAC may be thermally stable at temperature >800° C., |
| | suitable as an interdiffusion barrier |
| | for components working at higher |
| | temperature. e.g. multilayer barriers are |
| | frequently used. |
| | A thin deposited oxide layer can be |
| | synthesized at higher temperatures on MAFs |
| | without risk of atomic implantation/diffusion |
| | into the semiconductor layer (e.g. silicon (Si), |
| | indium gallium zinc oxide (IGZO), zinc |
| | oxide (ZnO) used in thin film transistors |
| | (TFTs), as the MAFs are able to block |
| | diffusion into the semiconductor layer. |
| Low temperature synthesis using laser CVD | MAFs can be grown on arbitrary surface and |
| process with a self-limiting growth | high aspect ratio surfaces, ideal for uniform |
| mechanism on a wide range of surfaces | monolayer/few layer deposition on electronic |
| | devices. |
| | Low process temperature (<300° C.) which |
| | means the barrier film can be grown directly |
| | on Cu and Co interconnects, or substrates |
| | used for OLED, TFTs and flexible |
| | electronics. Many existing deposition |
| | methods (e.g. |
| | PECVD, ALD) cannot grow high quality |
| | films at low temperatures (poorer barrier |
| | properties). Low temperature growth may |
| | also mean reduced reaction between |
| | deposited particles and the semiconductor |
| | layer. |
| | Self-limiting growth mechanism may allow |
| | for formation of continuous and uniform |
| | MAFs required for monolayer to few layers |
| | thickness. |
| | Process may be fast and scalable. |
| Flexibility and plasticity of MAFs | MACs show significant plasticity. Devices |
| | including MACs may deform without |
| | breaking. This may be important for flexible |
| | electronics in which major barrier failure |
| | originates from the cracks during bending, |
| | resulting in a catastrophic failure. |
| | MACs have more than 5 times lower |
| | Young's modulus compared to graphene, |
| | indicating higher flexibility. Similarly, other |
| | MAFs are expected to show higher flexibility as |
| | compared to their crystalline counterparts. |
| Insulating atomically thin carbon | A known form of atomically thin carbon is |
| | graphene, which is conductive and does not |
| | perform well for barriers for the following |
| | reasons: |
| | 1) in electronics, a conductive barrier layer |
| | may cause a short circuit between conductive |
| | interconnect lines; |
| | 2) galvanic corrosion may arise due to the |
| | delocalized electronic clouds on the graphene |
| | lattice (electronic conductivity). |
| | Both of the above issues can be avoided with |
| | insulating MAC barrier. |
| | Other MAFs may also be electrically |
| | insulating. |
| Insulating barrier material with high | Industry is constantly looking for an |
| thermal conductivity | insulating material that is simultaneously |
| | thermally conductive as well. The need for |
| | dissipating heat is important in |
| | nanoelectronics because of high-power |
| | density within the transistors. The barrier |
| | film may directly interface with the |
| | semiconductor active layer, and may function |
| | as a heat dissipation layer. |
| | MAFs may be thermally conductive while |
| | electrically insulating. |

### Structural Advantages of Monolayer Amorphous Carbon (MAC)

The atomic structure of MAC may be a continuous network of disordered sp² carbon (C) atoms in two dimensions (2D) without any grain boundaries (homogeneous), while conventional polycrystalline graphene may include ordered crystalline domains separated with grain-boundaries (inhomogeneous). In MAC, a ratio of hexagonal carbon rings to the non-hexagonal carbon rings may be less than 1, i.e. around 0.6. The advantages of MAC may include the following:

### 1. Corrosion/Oxidation Resistance

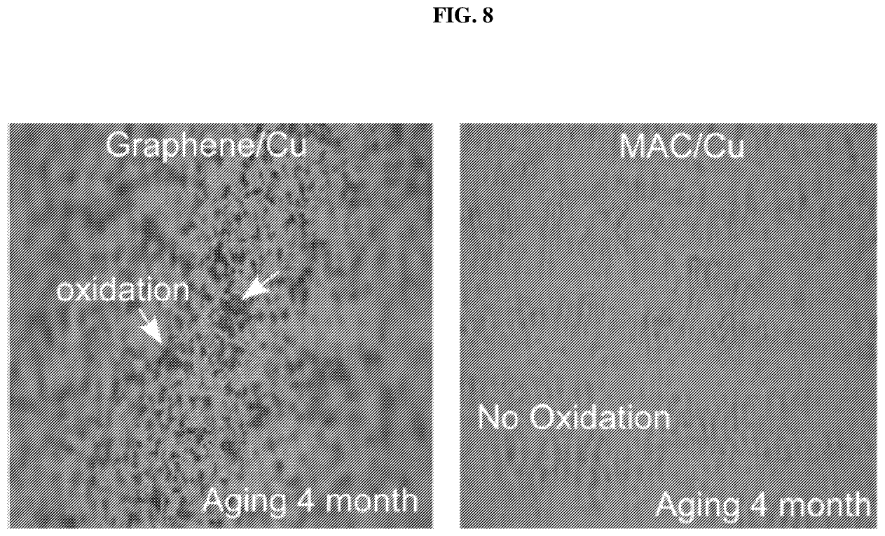

The grain boundaries in polycrystalline graphene barrier films may render inhomogeneity within the structure, by acting as preferential weaker sites and may be prone to attack by the reactive atmosphere (e.g. oxygen, moisture) impairing the barrier characteristics of the barrier films, rather accelerating the corrosion process in some cases. However, MAC may offer a homogenous atomic structure inhibiting the reactions of oxygen and moisture, thereby forming an efficient and stable barrier against harsh environment. FIG. 8 shows (left) an optical image of graphene encapsulated copper after 4 months of aging in ambient atmosphere; and (right) an optical image of monolayer amorphous carbon (MAC) encapsulated copper according to various embodiments after 4 months of aging in ambient atmosphere. It may be seen from FIG. 8 that monolayer amorphous carbon (MAC) encapsulated copper shows higher oxidation resistance compared to graphene encapsulated copper.

### 2. Thermal Stability

At higher temperatures, grain boundary sliding occurs in polycrystalline barrier films (e.g. tantalum (Ta), molybdenum (Mo), chromium (Cr), titanium nitride (TiN) etc.), making the structure unstable and causing the barrier films to lose functionality. Copper (Cu) ions may diffuse through grain boundaries. On the contrary, attributing to the homogeneous structure, MAC has shown thermal stability at temperature >700° C. Accordingly, MAC may have great potential as an effective barrier for components working at higher temperature, for example as diffusion barrier for interconnects. The homogeneous structure of MAC may give rise to its chemical stability and inertness.

### 3. Tunable Structure

The structure of the MAC may be tunable from completely amorphous to nanocrystalline, depending on the synthesis conditions, thereby widely allowing the tailoring of structure-property-performance according to end application requirements.

### 4. Mechanical Stability

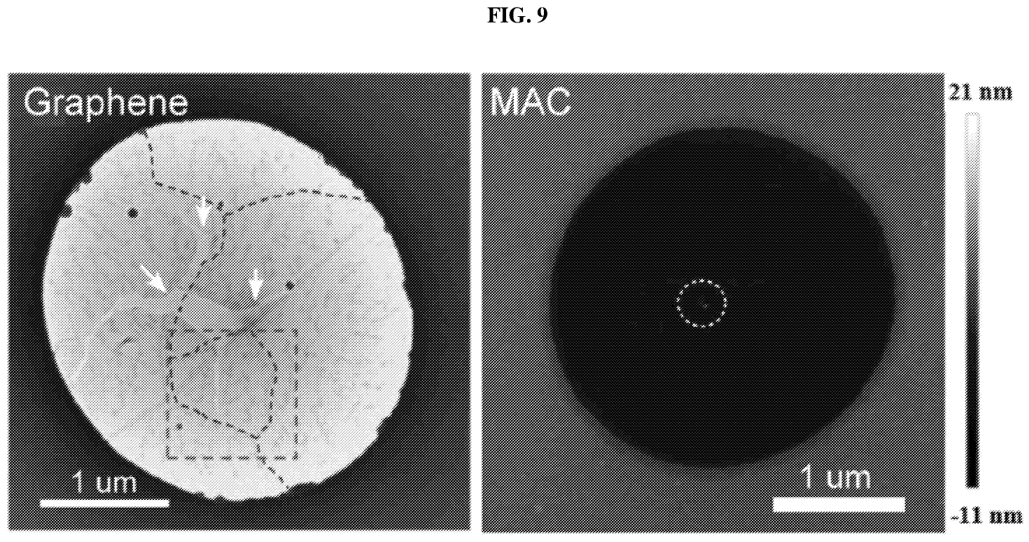

MAC may exhibit exceptionally high fracture toughness (in x, y, and z directions) attributed to its amorphous atomic structure with lack of grain boundaries, leading to the crack-arresting phenomenon during fracture. In contrast, for crystalline counterparts (e.g. polycrystalline graphene), cracks may propagate along the preferred crystal directions or grain boundaries, thereby diminishing the fracture toughness of the material. FIG. 9 shows (left) an optical image showing crack propagation along grain boundaries of graphene after indentation; and (right) an optical image of a monolayer amorphous carbon (MAC) film according to various embodiments showing lack of crack propagation after indentation.

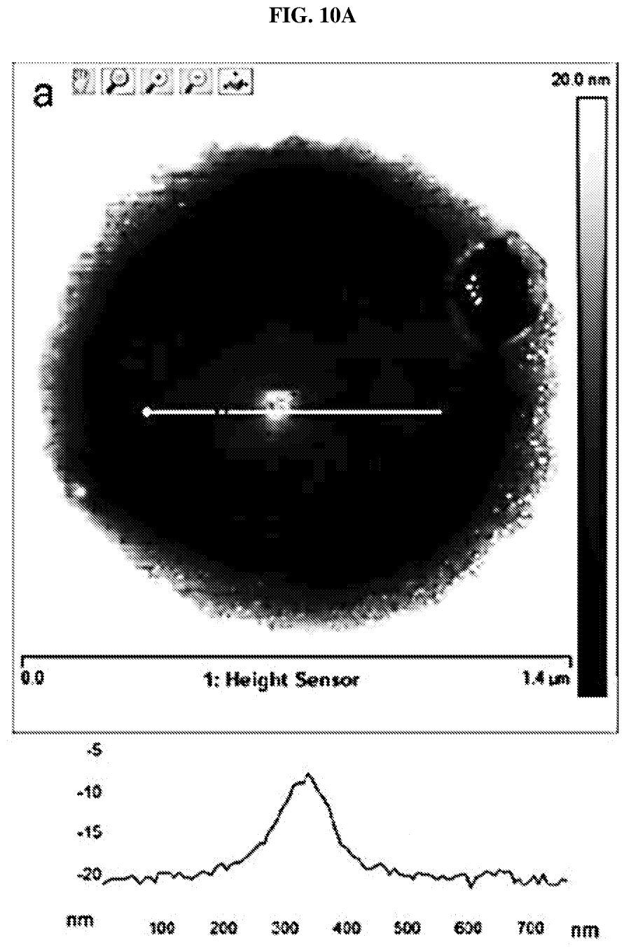

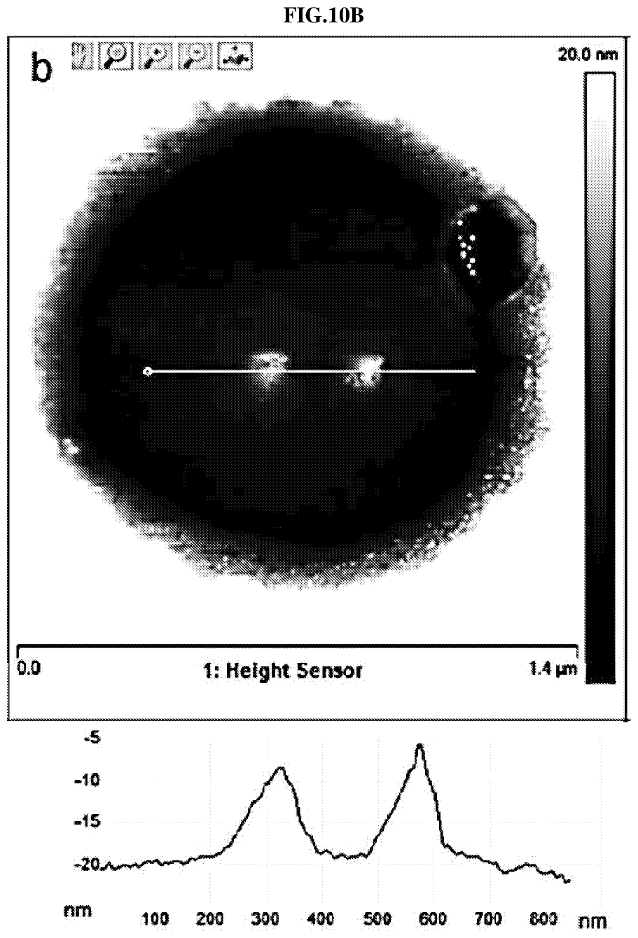

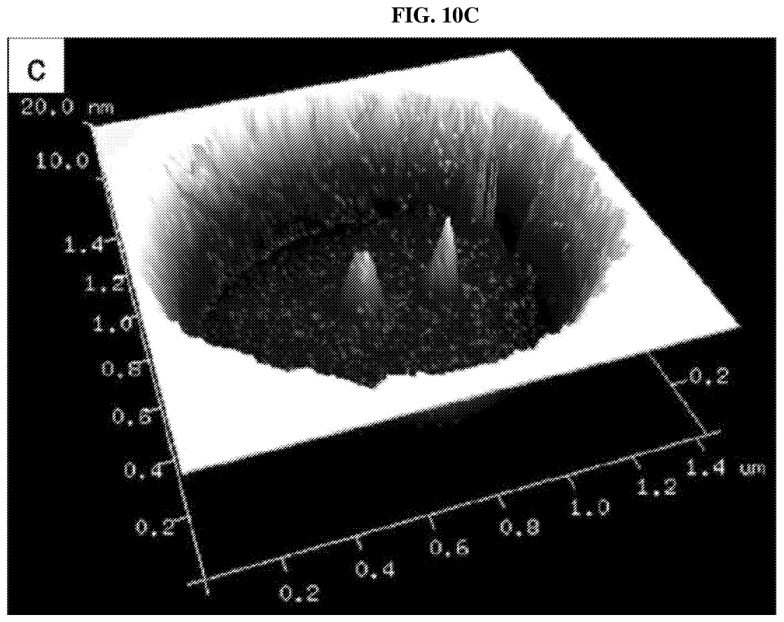

MAC may also exhibit high plasticity of >5% deformation without breaking, which is also critical to obtain a high fracture toughness. Significant plasticity has not been observed in conventional films previously. FIG. 10A shows (above) an atomic force microscopy (AFM) image of a suspended monolayer amorphous carbon (MAC) film according to various embodiments after an indentation is made on the film; and (below) a graph of height (in nanometers or nm) as a function of distance (in nanometers or nm) showing the corresponding height profile which shows an indentation peak after the AFM is pulled out of the monolayer amorphous carbon (MAC) film. FIG. 10B shows (above) another atomic force microscopy (AFM) image of the suspended monolayer amorphous carbon (MAC) film according to various embodiments after a second indentation is made on the film (on the right of the first indentation); and (below) a graph of height (in nanometers or nm) as a function of distance (in nanometers or nm) showing the corresponding height profile which shows a second indentation peak after the AFM is pulled out of the monolayer amorphous carbon (MAC) film. FIG. 10C shows a three-dimensional atomic force microscopy (AFM) image of the suspended monolayer amorphous carbon (MAC) film according to various embodiments with two indentations.

High fracture toughness may be crucial to enhance the durability and performance of barrier films according to various embodiments on flexible OLEDs, TFTs and other wearable electronic devices, which frequently experience cyclic stresses and bending. In comparison, the bending of conventional inorganic and polycrystalline barrier films (e.g. aluminum oxide (Al₂O₃), silicon nitride (SiN), zirconium oxide (ZrO₂)) may induce cracking, which act as the source of moisture/oxygen leakage limiting the lifetime of the barrier.

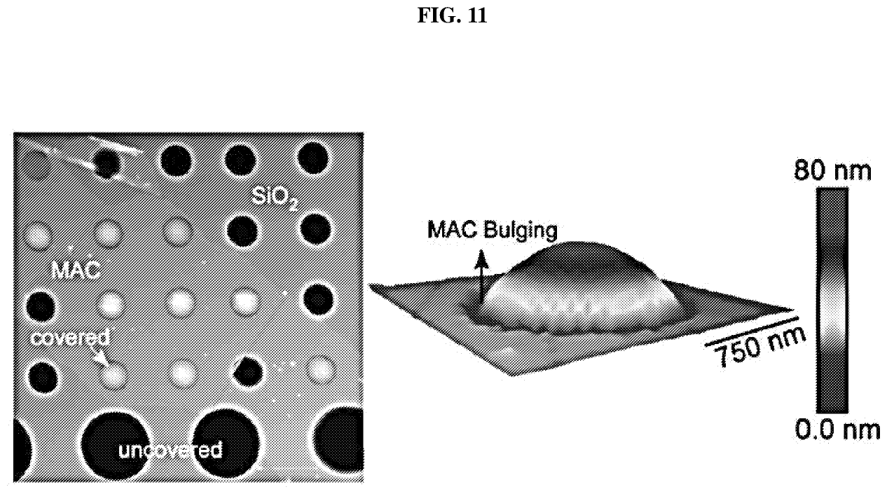

FIG. 11 shows (left) an optical image of a bubble test in which some holes are covered by monolayer amorphous carbon (MAC) films according to various embodiments and gas is introduced such that the monolayer amorphous carbon (MAC) films each forms a bulge; and (right) an atomic force microscopy (AFM) image showing the bulging of the monolayer film after removal from a higher pressure gas chamber. The bulging of the MAC films may remain even after 24 hours, indicating the effectiveness of the MAC films as a barrier material.

### 5. Atomically Thin

The single layer of MAC may have thickness of about 0.4 nm on a growth substrate, and may relax to 0.6 nm after transfer, making MAC an atomically thin barrier film for metallic diffusions for interconnects or an oxygen/moisture barrier for the OLED and TFTs. Atomically thin barrier film may be the key to achieve the efficient protection while minimally affecting the

performance of underlying substrate (conductivity of the Cu interconnects). Even if multilayer MAC film is required, the thickness may lie within the range of 1 nm-3 nm and may retain ultrathin features for the barrier film.

In contrast, the existing diffusion barriers (e.g. titanium nitride (TiN), or tantalum nitride (TaN)) may lose barrier functionality below 2-3 nm thickness, due to the non-uniformity and lack of continuity of the films. The required greater thicknesses of these conventional films may be detrimental to the flexibility of OLED displays, since displays including these films face the limitation of critical bending radius to avoid cracking.

### 6. Highly Transparent

Transparency of the barrier films may be critical to maintain the transparency of the OLED displays while the barrier films protecting the underlying materials from ambient atmosphere. Glass has traditionally been used as a barrier for the conventional displays. However, glass cannot be applied to flexible and foldable OLED displays owing to its rigidity. In addition, in relation to inorganic barrier material (e.g. aluminum oxide (Al₂O₃), silicon oxide (SiO₂) etc.), the minimum thickness to effectively block moisture of such barrier material results in significant transparency loss of the devices.

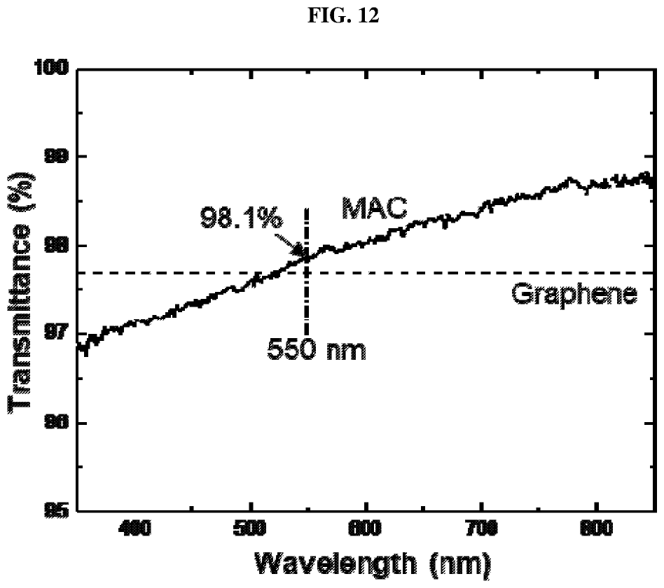

In contrast, MAC films may possess exceptionally high transparency of about 98.1% at 550 nm wavelength. FIG. 12 shows a plot of transmittance (in percent or %) as a function of wavelength (in nanometer or nm) illustrating the transmittance spectrum of monolayer amorphous carbon (MAC) according to various embodiments. FIG. 12 shows that MAC has a high transmittance of 98.1% at 550 nm and approaching 99% in the infrared spectrum. This is higher than that of graphene, which has a theoretical maximum of 97.7% at all visible wavelength. The nominal absorption of MAC may be accredited to its homogeneous atomic structure. If few layers (e.g. 5-10) of MAC are applied as a moisture barrier, about 2-4% of total transparency difference may be expected as compared to multilayer graphene barrier.

### 7. Thermally Conductive and Electrically Insulating

MAFs may be highly thermally conductive while being electrically insulating. Theory predictions suggest that monolayer amorphous materials do not suffer significant loss of thermal conductivity. MAC is found to be electrically insulating with about 100 GΩ/□ sheet resistance.

### MAC Processing Technology Advantages

MAC may be synthesized by laser chemical vapor deposition (LCVD), which can be integrated with existing semiconducting processing technology. LCVD is an industrially scalable process which may be able to achieve high throughput of large area barrier films. In addition, LCVD is an ultrafast technology, and an entire surface of the substrate may be covered with MAC in under 60 seconds. LCVD is more efficient than the widely employed atomic layer deposition (ALD) process.

Further, MAC may be synthesized at low temperatures of less than 300° C. This may mean that the barrier film can be grown directly on Cu interconnects as the low temperature required is compatible with silicon-based technologies. Also, the cost of MAC growth may be significantly lower as compared to graphene, which may consumer great amounts of energy when it is grown via thermal chemical vapor deposition at temperatures of about 1000° C. Further lowering of synthesis temperature (e.g. to <150° C.) may make it possible to enable direct MAC growth on polymeric substrates used for OLED and flexible electronics.

Graphene as a barrier film may not be directly grown on a polymeric substrate or on copper interconnects, and may require transfer from the growth substrate. However, the transfer may require a polymethylmethacrylate (PMMA) supporting layer, which may bring unwanted contaminants to the interfaces of the barrier film and the underlying device, thereby affecting the performances of the barrier film as well as the underlying device.

On the contrary, MAC films are mechanically stable, and freestanding membranes may be achievable. Therefore, transfer of freestanding MAC films onto a substrate may be possible without using a polymer supporting layer. Consequently, the bather film may be formed free of residues. Moreover, integration with the existing roll-to-roll transfer technology may also be possible to facilitate large area barrier films for OLED and flexible displays.

Forming a more effective barrier may generally require multilayers. However, uniform multilayer graphene may be challenging to produce. Currently, forming multilayer graphene may only be carried out using layer-by-layer transfer process, which is highly inefficient. In contrast, for MAC, a precise number of layers (e.g. 1-100) may be synthesized by LCVD, thereby allowing carefully tailoring the thickness of the barrier film for a specified application.

Moreover, MAC may be grown on arbitrary substrate, e.g. metals such as copper, gold, tungsten, titanium, aluminum, nickel etc., and insulators such as silicon oxide, strontium titanate (SrTiO₃), glass boron nitride (BN) etc. LCVD may enable growth of intricate shapes, thus allowing complete coverage of interconnects for effective barrier properties.

The direct growth of MAC may provide strong adhesion between the film and the substrate (up to >200 J/m²) comparing to CVD graphene, which has an adhesion of ˜10 J/m². Strong adhesion is required to avoid any film decoupling defects and interfacial failure resulting in deterioration of barrier properties.

MAC has been grown on copper (Cu) lines as an interdiffusion barrier. The MAC are grown using LCVD directly on the thin Cu lines interconnects without damaging the underlying layers. In addition, it has been demonstrated that MAC may act as a protection/interdiffusion barrier layer, as demonstrated by permeation, etching and acid tests.

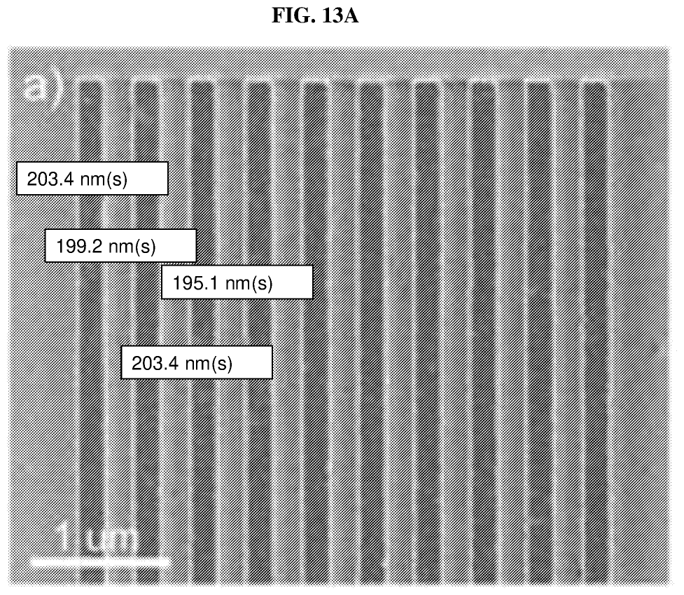

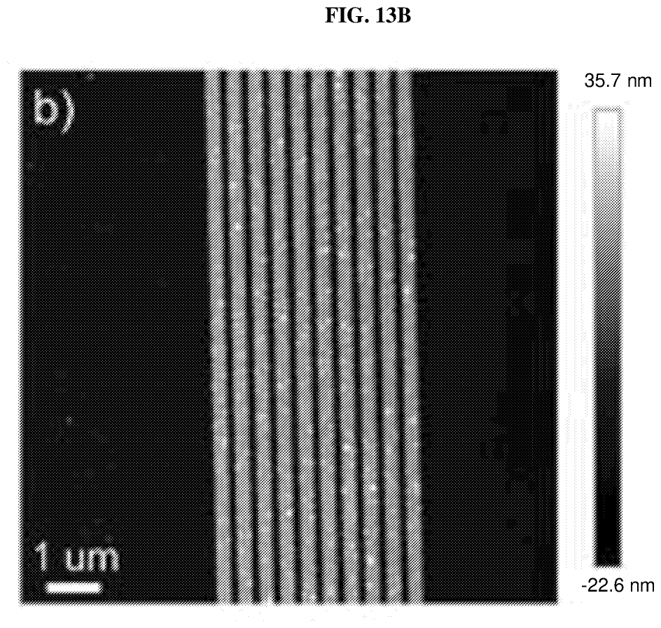

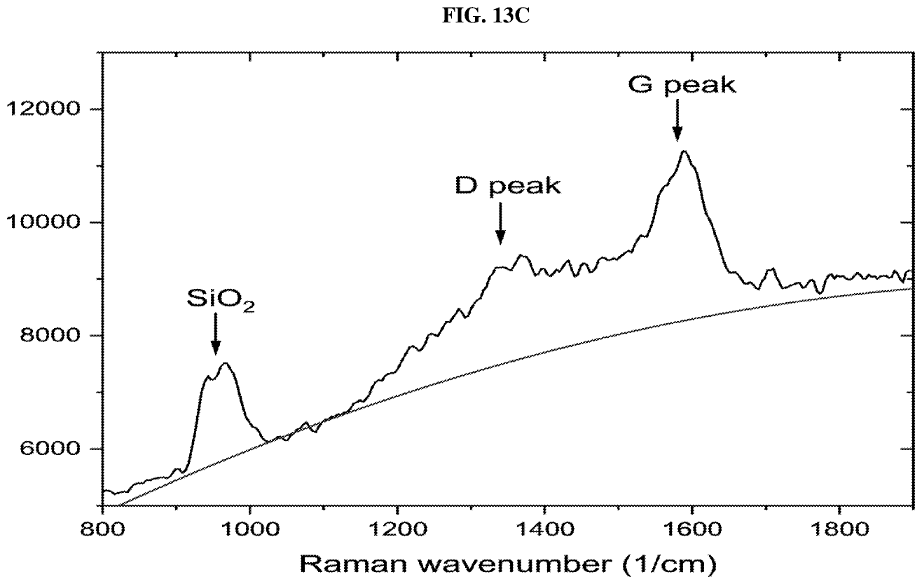

The copper lines (30 nm height, 200 nm width) were fabricated on a silicon oxide (SiO₂) wafer using e-beam lithography and subsequent e-beam evaporation of copper (Cu). Using laser assisted CVD, MAC is grown over the copper lines. FIG. 13A shows a scanning electron microscopy image of copper (Cu) lines after monolayer amorphous carbon (MAC) films are grown over the copper lines using laser chemical vapor deposition according to various embodiments. FIG. 13B shows an atomic force microscopy (AFM) image of copper (Cu) lines after monolayer amorphous carbon (MAC) films are grown over the copper lines using laser chemical vapor deposition according to various embodiments. FIG. 13C is a plot of Raman intensity (arbitrary units or a.u.) as a function of wavenumber (in per centimeter of 1/cm) showing the Raman spectrum of monolayer amorphous carbon (MAC)/copper (Cu) lines with D and G bands according to various embodiments.

The SEM and AFM images shown in FIGS. 13A-B reveal the shape and surface of the copper (Cu) lines remain intact and smooth after LCVD growth. In addition, FIGS. 13A-B also verify the feasibility of LCVD for direct growth of MAC, and that the growth of MAC may be implemented based on existing semiconducting processing technology. Raman spectrum taken from the Cu lines shows D and G bands, which are the characteristics peaks of MAC (sp²-C). These Raman features were consistent based on data taken from several points, indicating the uniformity of the MAC film grown on Cu lines.

It has also been found that while monolayer amorphous carbon (MAC) is highly permeable to protons (H+), the permeability is reduced by more than an order of magnitude for deuteron (˜2 times higher radius). This shows that MAC may be impermeable for ions or molecules bigger than protons. Based on measurements, MAC may be anticipated as a good barrier for gases (oxygen, air etc.) and moisture (H₂O), as well as a good interdiffusion barrier for metal and semiconductors (e.g. copper (Cu), cobalt (Co), silicon (Si), and so on).

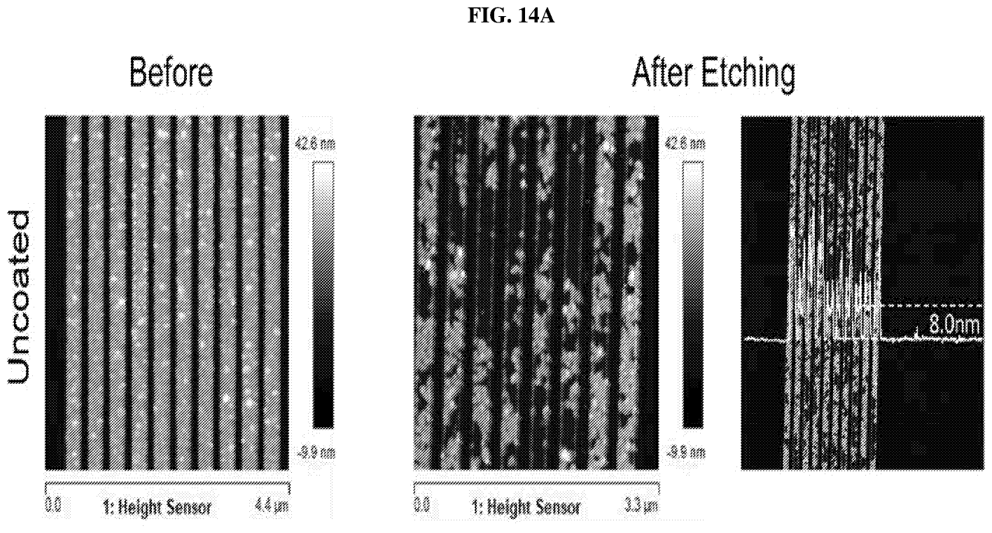

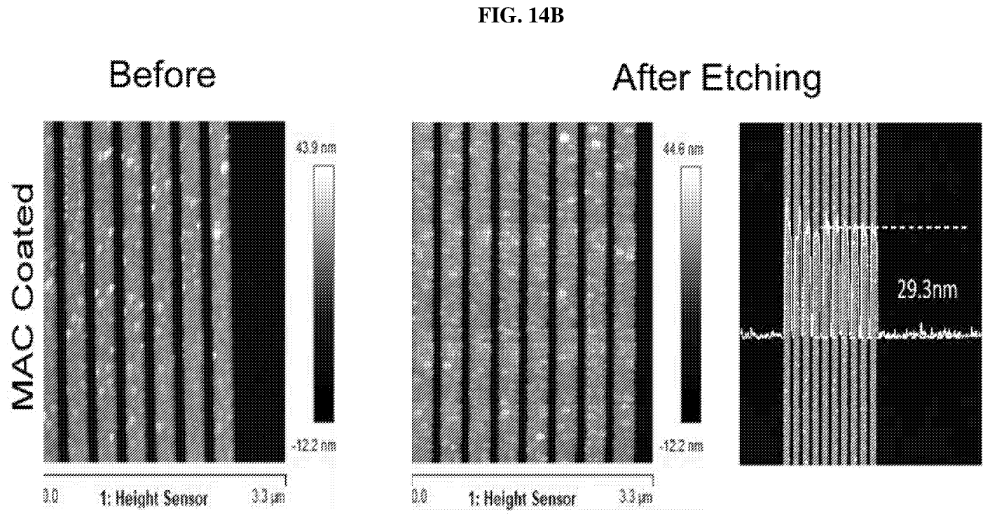

The uncoated and MAC-coated copper (Cu) lines may be exposed to Cu etchant ammonium persulfate, APS) to evaluate the barrier performance of MAC on Cu. FIG. 14A shows atomic force microscopy (AFM) images of (left) uncoated copper (Cu) lines before exposure to ammonium persulfate (APS); and (middle and right) the uncoated copper (Cu) lines after exposure to ammonium persulfate (APS). FIG. 14A reveals that the uncoated Cu lines underwent severe etching after exposing to APS solution. The height profile of uncoated Cu lines was decreased from −30 nm to −8.0 nm, and the roughness root-mean-square (rms) was increased from 1.8 nm to 6.5 nm.

On the contrary, MAC coated Cu lines remained smooth and un-etched after APS exposure. FIG. 14B shows atomic force microscopy (AFM) images of (left) monolayer amorphous carbon (MAC)-coated copper (Cu) lines according to various embodiments before exposure to ammonium persulfate (APS); and (middle and right) the monolayer amorphous carbon (MAC)-coated copper (Cu) lines according to various embodiments after exposure to ammonium persulfate (APS). The height profile and rms roughness of MAC-coated Cu lines barely changed and were measured as 29.3 nm and 1.7 nm, respectively.

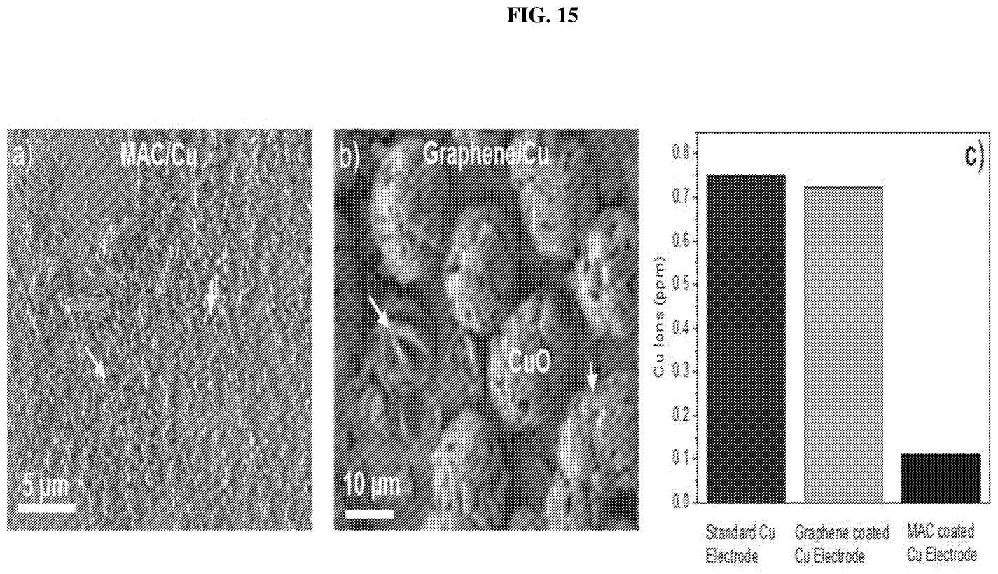

Acid etching tests were also performed on bare, graphene, and MAC coated Cu lines. Samples were exposed to nitric acid. FIG. 15 shows (left) a scanning electron microscopy (SEM) image of monolayer amorphous carbon (MAC) coated copper (Cu) foils according to various embodiments after being exposed to acid; (middle) graphene coated copper (Cu) foils after being exposed to acid; and (right) a plot comparing the copper (Cu) ions lost (in parts per million or ppm) of a standard copper (Cu) electrode, a graphene coated (Cu) electrode, and a monolayer amorphous carbon (MAC) coated copper (Cu) electrode according to various embodiments. The SEM images in FIG. 15 shows that MAC coated copper foil has significantly less copper oxide formation after the corrosion test as compared to graphene coated foil. As shown in the plot, MAC coated copper electrode has about 7× less copper ion loss from acid etch test compared to that of the standard (bare) copper electrode and the graphene coated electrode. These results clearly indicate MAC as an effective barrier layer over Cu lines/interconnections, protecting them from chemicals.

As highlighted above, various embodiments may relate to a device including one or more monolayer amorphous films (MAFs), such as one or more monolayer amorphous carbon (MAC) film, on a semiconductor or polymeric substrate. There may be, for instance, any number of layers selected from 1-10 of MAC films, depending on barrier permeation and mechanical requirements.

Various embodiments may relate to a device including one or more MAFs as part of a multilayer barrier e.g. aluminum oxide (Al₂O₃)/MAC/silicon (Si). Various embodiments may relate to a device including a composite barrier film including one or more monolayers, followed by a thin barrier layer of another material, such as Al₂O₃. This may allow for an overall much thinner barrier to meet the same barrier performance requirements.

Direct growth of thin MAC (1-10 layers) barrier film on a polymeric substrate of OLED or TFT may result in strong interfacial adhesion between the barrier layer and the flexible substrate. Stronger interfacial adhesion may allow higher degree of bending (radius <1 mm) of devices while avoiding the cracks or delamination of the MAC barrier film, permitting greater flexibility while keeping intact barrier performance. Additionally, plasticity (>5%) and higher fracture toughness of MAC can greatly enhance the durability of the barrier film on flexible devices, such that despite having minor cracks/voids in the barrier film (due to accidents), cyclic stresses may still be sustained without causing any breakage of the film, hence preventing catastrophic damage to the barrier film, and flexible device performance from being affected. The LCVD process may also induce strong interfacial adhesion of MAC with the substrate. In flexible applications, induced strain may delaminate barrier layers that lead to film fractures and device failure. The strong interfacial adhesion of MAC to the surface it is synthesized on may be critical. Furthermore, the MAC may act as a strong adhesion layer for subsequent film deposition. As such, MAFs such as MAC films may address a key failure mechanism in flexible electronics.

The defect-free atomically stitched continuous MAFs barrier layer can be grown directly on target substrate, which effectively blocks water or oxygen molecules penetration. Various embodiments may help to circumvent existing drawbacks of state-of-the-art inorganic barrier films deposited by ALD with pinhole defects, which lead to defect-mediated moisture permeation and diminishing of the barrier performance. Densely packed atomic structure of MAC with absence of defects/pinholes may be devoid of preferential sites for moisture or oxygen permeation. This may form a suitable barrier film which is expected to keep the water vapor transmission rate (WVTR) at less than 10⁻⁵ g m⁻² day⁻¹ (at least 2 orders of magnitude higher than graphene 10-3-10-1 g m-2 day-1) and oxygen penetration content at less than 10^{-∝}cc m⁻² day⁻¹. MAC as an interdiffusion barrier may also allow for subsequent growth of higher quality barrier layers because higher temperature PECVD/ALD deposition of oxide barriers is possible without diffusion damage to the underlying substrate (silicon oxide (SiO₂), polyethylene terephthalate (PET) etc.).

A MAC interdiffusion barrier layer may be between two metal contacts such as gate metal stacks (aluminum (Al), titanium (Ti), tantalum (Ta), copper (Cu), nickel (Ni), gold (Au), chromium (Cr) etc.) may prevent interdiffusion and commonly observed alloying between the metal contacts at elevated operational temperature (>450° C.). In addition, the dielectric breakdown of SiO₂/metal contacts by interdiffusion at elevated temperature can also be avoided by insertion of a MAC barrier layer.

Higher thermal stability (>700° C.) and thermal conduction of MAC barrier layer may allow for thinner Cu interconnects. The MAC barrier layer may allow for carrying higher current density which causes heat. As the MAC barrier layer is thermally conductive, the thermal diffusion may ensure stability and that excessively elevated temperatures are not reached. A conventional interdiffusion barrier layer may be thermally insulating, and is hence unable to dissipate heat, thereby resulting in breakdown of the diffusion barrier.

The electrically insulating characteristics of MAC barrier layer may concurrently avoid the short-circuiting of the thin Cu interconnections.

A heat spreader may be important to regulate peak temperatures of the transistors, therefore improving device performance that is currently limited by the local heat load. Higher thermal conduction of the electrically insulating MAC diffusion barrier layer may enable efficient thermal management of the high-power density devices. MAC may therefore meet the requirements as heat spreaders, which is important in nanoelectronics because of the high-power density within the transistors. The MAC barrier layer may directly interface with the semiconductor active layer and may be suited to function as a heat dissipation layer.

Various embodiments may relate to MAFs as potential barrier layers for applications such as a diffusion barrier layer for metallic interconnects (Cu) within integrated circuits (ICs) of electronic components and microelectronic devices, or a gas and moisture barrier layer for ambient atmosphere sensitive applications such as organic light emitting diodes (OLEDs) and other flexible electronic components, or in high temperature oxidation resistant components.

Various embodiments may relate to MAFs including, but not limited to MAC films. Other MAFs of varying compositions may be synthesized using LCVD to form mono-elemental films to multi components composite films for various barrier applications.

Embodiments may include, but are not limited to the following:

(A) An electronic device including a substrate including a suitable semiconductor or a suitable polymeric material; and a barrier including one or more monolayer amorphous films over the substrate; wherein the barrier is configured to inhibit or reduce permeation of moisture or gas from environment to the substrate.

(B) The electronic device according to statement (A), wherein the one or more monolayer amorphous films are monolayer amorphous carbon films, amorphous boron nitride films, monolayer amorphous molybdenum disulfide films, monolayer amorphous tungsten disulfide films, monolayer amorphous borophene films, monolayer amorphous transition metal dichalcogenide films, monolayer amorphous boron carbon nitride films, or heterogenous atomic doped films or alloys.

(C) The electronic device according to statement (A) or statement (B), wherein each of the one or more monolayer amorphous films has a thickness selected from a range from 0.4 nm to 1 nm.

(D) The electronic device according to any one of statements (A) to (C), wherein the one or more monolayer amorphous films form a stack.

(E) The electronic device according to any one of statements (A) to (D), further including a protective layer over the substrate.

(F) The electronic device according to statement (E), wherein the protective layer includes an oxide or a polymer.

(G) The electronic device according to statement (F), wherein the oxide is aluminum oxide or hafnium oxide.

(H) The electronic device according to statement (F), wherein the polymer is parylene C.

(I) The electronic device according to any one of statements (E) to (H), wherein the one or more monolayer amorphous films are between the protective layer and the substrate.

(J) The electronic device according to any one of statements (E) to (H), wherein the protective layer is between the one or more amorphous films and the substrate.

(K) The electronic device according to any one of statements (A) to (J), wherein the electronic device is an organic light emitting diode or a thin film transistor.

(L) The electronic device according to any one of statements (A) to (K), wherein a bond ratio of sp³/sp² present in the one or more monolayer amorphous films is 0.1 or less.

(M) The electronic device according to any one of statements (A) to (L), wherein the one or more monolayer amorphous films have an oxygen penetration content of less than 10⁻⁴ cc m⁻² day⁻¹; and wherein the one or more monolayer amorphous films have a water vapor transmission rate of less than 10⁻⁵ g m⁻² day⁻¹.

(N) A method of forming an electronic device, the method including forming a barrier including one or more monolayer amorphous films over a substrate; wherein the substrate includes a suitable semiconductor or a suitable polymeric material; and wherein the barrier is configured to inhibit or reduce permeation of moisture or gas from environment to the substrate.

(O) The method according to statement (N), wherein the one or more monolayer amorphous films are formed on the substrate via a chemical vapor deposition process.

(P) The method according to statement (O), wherein the chemical vapor deposition process is a laser chemical vapor deposition process.

(Q) The method according to statement (O) or statement (P), wherein a temperature in which the chemical vapor deposition process is carried out is any suitable temperature below 300° C.

(R) The method according to statement (N), wherein the one or more monolayer amorphous films are formed as free-standing films before being transferred onto the substrate.

(S) An electronic device including a first device structure including an electrically conductive material; a second device structure including a further electrically conductive material or a semiconductor material; and a barrier including one or more monolayer amorphous films between the first device structure and the second device structure; wherein the barrier is configured to inhibit or reduce interdiffusion between the first device structure and the second device structure.

(T) The electronic device according to statement (S), wherein the electrically conductive material is a metal, a metal alloy, a doped metal oxide, or conductive carbon.

(U) The electronic device according to statement (T), wherein the metal is copper or cobalt.

(V) The electronic device according to any one of statements (S) to (U), wherein the further electrically conductive material is a metal, a metal alloy, a doped metal oxide, or conductive carbon.

(W) The electronic device according to any one of statements (S) to (V), wherein the semiconductor material is silicon.

(X) The electronic device according to any one of statements (S) to (W), wherein the electronic device is a transistor, a diode, a memory device, an electro-mechanical device, an integrated circuit chip, a microprocessor, or an electronic sensing device.

(Y) The electronic device according to any one of statements (S) to (X), wherein the first device structure is an interconnect; and wherein the second device structure is a substrate.

(Z) The electronic device according to any one of statements (S) to (X), wherein the first device structure is a first interconnect; and wherein the second device structure is a second interconnect.

(AA) The electronic device according to any one of statements (S) to (Z), wherein a bond ratio of sp³/sp² present in the one or more monolayer amorphous films is 0.1 or less.

(AB) A circuit arrangement including the electronic device according to any one of statements (S) to (AA).

(AC) A method of forming an electronic device, the method including forming a first device structure including an electrically conductive material; forming a second device structure including a further electrically conductive material or a semiconductor material; and forming a barrier including one or more monolayer amorphous films between the first device structure and the second device structure; wherein the barrier is configured to inhibit or reduce interdiffusion between the first device structure and the second device structure.

(AD) The method according to statement (AC), wherein the first device structure is formed over the one or more monolayer amorphous films after forming the one or more monolayer amorphous films over the second device structure such that the one or more monolayer amorphous films are between the first device structure and the second device structure.

(AE) The method according to statement (AC) or statement (AD), wherein the one or more monolayer amorphous films are formed via a chemical vapor deposition process.

(AF) The method according to statement (AE), wherein the chemical vapor deposition process is a laser chemical vapor deposition process.

(AG) The method according to statement (AE) or statement (AF), wherein a temperature in which the chemical vapor deposition process is carried out is any suitable temperature below 300° C.

(AH) The method according to statement (AC), wherein the one or more monolayer amorphous films are formed as free-standing films before being transferred over the second device structure.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

We claim:

1. An electronic device comprising:
a substrate comprising a suitable semiconductor or a suitable polymeric material; and
a barrier comprising one or more monolayer amorphous films over the substrate, each of the one or more monolayer amorphous films being a one-atom thick layer having a thickness selected from a range from 0.4 nm to 1 nm, with a bond ratio of sp³/sp² present in the one or more monolayer amorphous films being 0.1 or less;
wherein each of the one or more monolayer amorphous films is continuous and devoid of grain boundaries such that the barrier is configured to inhibit or reduce permeation of moisture or gas from environment to the substrate, the one or more monolayer amorphous films having a water vapor transmission rate of less than 10⁻⁵ g m⁻² day⁻¹.

2. The electronic device according to claim 1,
wherein the one or more monolayer amorphous films are monolayer amorphous carbon films, amorphous boron nitride films, monolayer amorphous borophene films, or monolayer amorphous boron carbon nitride films.

3. The electronic device according to claim 1,
wherein the one or more monolayer amorphous films form a stack; and/or further comprising a protective layer over the substrate.

4. (canceled)

5. The electronic device according to claim 3,
wherein the protective layer comprises an oxide or a polymer, and optionally
wherein the oxide is aluminum oxide or hafnium oxide, and/or
wherein the polymer is parylene C.

6. (canceled) (Cancelled)

8. The electronic device according to claim 4,
wherein the one or more monolayer amorphous films are between the protective layer and the substrate; and/or
wherein the protective layer is between the one or more amorphous films and the substrate.

9. (canceled)

10. The electronic device according to claim 1,
wherein the electronic device is an organic light emitting diode or a thin film transistor; and optionally
wherein the organic light emitting diode comprises:
a first electrode;
a second electrode;
an organic emission layer between the first electrode and the second electrode; and
wherein the substrate is the second electrode or the organic emission layer which the barrier is arranged on;
or
wherein the thin film transistor comprises:
a semiconductor layer;
a dielectric layer on the semiconductor layer;
a gate electrode on the dielectric layer;
a drain electrode and a source electrode at least partially embedded in the semiconductor layer and on a first side of the dielectric layer;
wherein the gate electrode is on a second side of the dielectric layer opposite the first side:
or
wherein the thin film transistor comprises:
a gate electrode;
a dielectric layer on the gate electrode;
a drain electrode and a source electrode on or over the dielectric layer; and
a semiconductor layer over the drain electrode and the source electrode;
wherein the semiconductor layer is the substrate which the barrier is on.

11. (canceled)

12. (canceled)

13. (canceled)

14. The electronic device according to claim 1,
wherein the one or more monolayer amorphous films have an oxygen penetration content of less than 10⁻⁴ cc m⁻² day⁻¹, and/or wherein the barrier is configured to inhibit or reduce permeation of the moisture or the gas from the environment to the substrate by blocking ions or molecules bigger than protons.

15. (canceled)

16. A method of forming an electronic device, the method comprising:
forming a barrier comprising one or more monolayer amorphous films over a substrate, each of the one or more monolayer amorphous films being a one-atom thick layer having a thickness selected from a range from 0.4 nm to 1 nm, with a bond ratio of sp³/sp² present in the one or more monolayer amorphous films being 0.1 or less;
wherein the substrate comprises a suitable semiconductor or a suitable polymeric material; and
wherein each of the one or more monolayer amorphous films is continuous and devoid of grain boundaries such that the barrier is configured to inhibit or reduce permeation of moisture or gas from environment to the substrate, the one or more monolayer amorphous films having a water vapor transmission rate of less than 10⁻⁵ g m⁻² day⁻¹¹.

17. The method according to claim 16,
wherein the one or more monolayer amorphous films are formed on the substrate via a chemical vapor deposition process, and/or wherein the chemical vapor deposition process is a laser chemical vapor deposition process, and/or wherein a temperature in which the chemical vapor deposition process is carried out is any suitable temperature below 300° C.

18. (canceled)

19. (canceled)

20. The method according to claim 16,
wherein the one or more monolayer amorphous films are formed as free-standing films before being transferred onto the substrate, and/or wherein the electronic device is an organic light emitting diode or a thin film transistor.

21. (canceled)

22. The method according to claim 20,
wherein the organic light emitting diode comprises:
a first electrode;
a second electrode;
an organic emission layer between the first electrode and the second electrode; and
wherein the substrate is the second electrode or the organic emission layer which the barrier is arranged on; or
wherein the thin film transistor comprises:
a semiconductor layer;
a dielectric layer on the semiconductor layer;
a gate electrode on the dielectric layer;
a drain electrode and a source electrode at least partially embedded in the semiconductor layer and on a first side of the dielectric layer;
wherein the gate electrode is on a second side of the dielectric layer opposite the first side; or
wherein the thin film transistor comprises:
a gate electrode;
a dielectric layer on the gate electrode;
a drain electrode and a source electrode on or over the dielectric layer; and
a semiconductor layer over the drain electrode and the source electrode;
wherein the semiconductor layer is the substrate which the barrier is on.

23. (canceled)

24. (canceled)

25. The method according to claim 16,
wherein the barrier is configured to inhibit or reduce permeation of the moisture or the gas from the environment to the substrate by blocking ions or molecules bigger than protons.

26. An electronic device comprising:
a first device structure comprising an electrically conductive material;
a second device structure comprising a further electrically conductive material or a semiconductor material; and
a barrier consisting of one or more monolayer amorphous films between and in contact with the first device structure and the second device structure, each of the one or more monolayer amorphous films being a one-atom thick layer having a thickness selected from a range from 0.4 nm to 1 nm, with a bond ratio of sp³/sp² present in the one or more monolayer amorphous films being 0.1 or less;
wherein each of the one or more monolayer amorphous films is continuous and devoid of grain boundaries such that the barrier is configured to inhibit or reduce interdiffusion between the first device structure and the second device structure; and
wherein the first device structure is an interconnect, and the second device structure is a substrate or a further interconnect.

27. The electronic device according to claim 26,
wherein the electrically conductive material is a metal, a metal alloy, a doped metal oxide, or conductive carbon, and/or wherein the further electrically conductive material is a metal, a metal alloy, a doped metal oxide, or conductive carbon.

28. The electronic device according to claim 27,
wherein the metal is copper or cobalt.

29. (canceled)

30. The electronic device according to claim 26,
wherein the semiconductor material is silicon.

31. The electronic device according to claim 26,
wherein the electronic device is a transistor, a diode, a memory device, an electro-mechanical device, an integrated circuit chip, a microprocessor, or an electronic sensing device.

32. (canceled)

33. A method of forming an electronic device, the method comprising:
forming a first device structure comprising an electrically conductive material;
forming a second device structure comprising a further electrically conductive material or a semiconductor material; and
forming a barrier consisting of one or more monolayer amorphous films between and in between the first device structure and the second device structure, each of the one or more monolayer amorphous films being a one-atom thick layer having a thickness selected from a range from 0.4 nm to 1 nm, with a bond ratio of sp3/sp2 present in the one or more monolayer amorphous films being 0.1 or less;
wherein each of the one or more monolayer amorphous films is continuous and devoid of grain boundaries such that the barrier is configured to inhibit or reduce interdiffusion between the first device structure and the second device structure; and
wherein the first device structure is an interconnect, and the second device structure is a substrate or a further interconnect.

34. The method according to claim 33,
wherein the first device structure is formed over the one or more monolayer amorphous films after forming the one or more monolayer amorphous films over the second device structure such that the one or more monolayer amorphous films are between the first device structure and the second device structure.

35. The method according to claim 33,
wherein the one or more monolayer amorphous films are formed via a chemical vapor deposition process, and optionally
wherein the one or more monolayer amorphous films are formed as free-standing films before being transferred over the second device structure; and/or
wherein a temperature in which the chemical vapor deposition process is carried out is any suitable temperature below 300° C.

36. (canceled)

37. (canceled)

38. (canceled)
